(19) United States
(12) Patent Application Publication
(10) Pub. No.: US 2025/0311232 A1
(43) Pub. Date: Oct. 2, 2025

(54) 3D FeRAM DEVICES

(71) Applicant: Samsung Electronics Co., Ltd., Suwon-si (KR)

(72) Inventors: Haewook Jeong, Suwon-si (KR); Keonhee Park, Suwon-si (KR)

(21) Appl. No.: 19/062,854

(22) Filed: Feb. 25, 2025

(30) Foreign Application Priority Data
Mar. 26, 2024 (KR) 10-2024-0040956

(51) Int. Cl. H10B 53/20; G11C 11/22; H10B 53/10; H10B 53/30; H10B 53/40

(52) U.S. Cl. CPC H10B 53/20; G11C 11/221; G11C 11/2273; G11C 11/2275; H10B 53/10; H10B 53/30; H10B 53/40

(57) ABSTRACT

A 3D FeRAM device includes bit lines each extending in a first direction on a substrate, block selection lines each extending in a second direction on the bit lines, word lines each extending in the second direction on a corresponding one of the block selection lines, channels each extending in a third direction through one of the block selection lines and some of the word lines arranged in the third direction on an upper surface of a corresponding one of the bit lines, a plate line extending in the second direction and contacting upper surfaces of channels arranged in the second direction, and capacitor structures each including capacitor electrodes and ferroelectric patterns alternately stacked in the third direction on a corresponding one of the bit lines. The capacitor electrodes of each of the capacitor structures contact and are electrically connected to a corresponding one of the channels.

### CROSS-REFERENCE TO RELATED APPLICATION

This application claims priority under 35 U.S.C. § 119 to Korean Patent Application No. 10-2024-0040956, filed on Mar. 26, 2024 in the Korean Intellectual Property Office (KIPO), the disclosure of which is incorporated by reference herein in its entirety.

### TECHNICAL FIELD

Example embodiments of the inventive concept relate to a 3D ferroelectric random access memory (FeRAM) device.

### DISCUSSION OF RELATED ART

A ferroelectric random access memory (FeRAM) device or a ferroelectric field effect transistor (FeFET) may be used as a memory device, which is simpler than a DRAM device, and a non-volatile memory device as a flash memory device. Recently, a 3-dimensional (3D) FeRAM device has been developed in order to have a high integration degree, however, an enhanced method of manufacturing the 3D FeRAM device is needed.

### SUMMARY

Example embodiments of the inventive concept provide a 3D FeRAM device having an enhanced integration degree.

According to example embodiments of the inventive concept, there is provided a 3D FeRAM device. The 3D FeRAM device may include bit lines, block selection lines, word lines, channels, a plate line and capacitor structures. The bit lines may be disposed on a substrate, and each of the bit lines may extend lengthwise in a first direction parallel to an upper surface of the substrate. The bit lines may be spaced apart from each other in a second direction parallel to the upper surface of the substrate and crossing the first direction. The block selection lines may be disposed on the bit lines, and each of the block selection lines may extend lengthwise in the second direction. The block selection lines may be spaced apart from each other in the first direction. A set of word lines may be disposed on each of the block selection lines, and each of the word lines for each set may extend lengthwise in the second direction. The word lines in each set of word lines may be spaced apart from each other in a third direction perpendicular to the upper surface of the substrate. The channels may be spaced apart from each other in the first direction and the second direction, and each of the channels may extend lengthwise in the third direction through one of the block selection lines and a corresponding set of the word lines arranged in the third direction on an upper surface of a corresponding one of the bit lines. The plate line may extend lengthwise in the second direction and contact upper surfaces of the channels arranged in the second direction. The capacitor structures may be spaced apart from each other in the first direction, and each of the capacitor structures may include capacitor electrodes and ferroelectric patterns alternately stacked in the third direction on a corresponding one of the bit lines. The capacitor electrodes of each of the capacitor structures may contact and be electrically connected to a corresponding one of the channels.

According to example embodiments of the inventive concept, there is provided a 3D FeRAM device. The 3D FeRAM device may include a bit line, a block selection line, word lines, a channel, a plate line and a capacitor structure. The bit line may be disposed on a substrate, and the bit line may extend lengthwise in a first direction parallel to an upper surface of the substrate. The block selection line may be disposed on the bit line, and the block selection line may extend lengthwise in a second direction parallel to the upper surface of the substrate and crossing the first direction. The word lines may be disposed on the block selection line, and each of the word lines may extend lengthwise in the second direction. The word lines may be spaced apart from each other in a third direction perpendicular to the upper surface of the substrate. The channel may contact an upper surface of the bit line, and the channel may be adjacent to the block selection line and the word lines and extending lengthwise in the third direction. The plate line may contact an upper surface of the channel. The capacitor structure may include capacitor electrodes and ferroelectric patterns alternately stacked in the third direction on the bit line. The capacitor electrodes of the capacitor structure may contact and be electrically connected to the channel. Each of the word lines may overlap a corresponding one of the ferroelectric patterns in the first direction. A thickness of each of the word lines in the third direction may be less than a thickness of the corresponding one of the ferroelectric patterns in the third direction.

According to example embodiments of the inventive concept, there is a 3D FeRAM device. The 3D FeRAM device may include bit lines, block selection lines, word lines, channels, gate insulation patterns, plate lines, insulation patterns, and capacitor structures. The bit lines may be disposed on a substrate, and each of the bit lines may extend lengthwise in a first direction parallel to an upper surface of the substrate. The bit lines may be spaced apart from each other in a second direction parallel to the upper surface of the substrate and crossing the first direction. The block selection lines may be disposed on the bit lines, and each of the block selection lines may extend lengthwise in the second direction. The block selection lines may be spaced apart from each other in the first direction. A set of word lines may be disposed on each of the block selection lines, and each of the word lines for each set may extend lengthwise in the second direction. The word lines in each set may be spaced apart from each other in a third direction perpendicular to the upper surface of the substrate. The channels may be spaced apart from each other in the first direction and in the second direction, and each of the channels may extend lengthwise in the third direction through one of the block selection lines and a corresponding set of the word lines arranged in the third direction on an upper surface of a corresponding one of the bit lines. A gate insulation pattern may be disposed between each of the channels and a corresponding one of the block selection lines and between each of the channels and a corresponding one of the word lines. The plate lines each may contact upper surfaces of the channels arranged in the second direction, and the plate lines may be spaced apart from each other in the first direction. The insulation patterns may be disposed on each of the bit lines. The capacitor structures may be spaced apart from each other in the first direction, and each of the capacitor structures may include capacitor electrodes and ferroelectric patterns alternately stacked in the third direction on each of the insulation patterns. The capacitor electrodes of each of the capacitor structures may contact and be electrically connected to a corresponding one of the channels. Each of the channels, a corresponding one of the block selection lines and a corresponding set of the word lines surrounding the corresponding channel, capacitor electrodes of a corresponding one of the capacitor structures contacting the corresponding channel, and the ferroelectric patterns between the capacitor electrodes may collectively form a memory cell chain. A plurality of memory cell chains arranged in the second direction may collectively form a memory cell block.

The 3D FeRAM device in accordance with example embodiments may have an enhanced integration degree.

### BRIEF DESCRIPTION OF THE DRAWINGS

FIGS. 1 to 3 are a perspective view, a plan view and a cross-sectional view, respectively, illustrating a 3D ferroelectric random access memory (FeRAM) device in accordance with example embodiments.

FIGS. 4 and 5 are circuit diagrams illustrating a program operation of each memory cell included in a ferroelectric memory device.

FIGS. 6 to 8 show circuit diagrams, hysteresis curves and a voltage graph for explaining a read operation of each memory cell included in a ferroelectric memory device.

FIGS. 9 and 10 show circuit diagrams and hysteresis curves for explaining a standby state and an active state of a chain memory cell string including the ferroelectric capacitor chain when ferroelectric capacitors are connected to each other in series to form a ferroelectric capacitor chain.

FIG. 11 is a circuit diagram illustrating an electrical connection of memory cells disposed between a bit line and a plate line in a 3D FeRAM device in accordance with example embodiments, and FIG. 12 is a drawing illustrating an operation of the memory cells.

FIGS. 13 to 22 are plan views and cross-sectional views illustrating a method of manufacturing a 3D FeRAM device in accordance with example embodiments.

FIGS. 23 to 25 are perspective views illustrating 3D FeRAM devices in accordance with example embodiments.

### DETAILED DESCRIPTION OF THE EMBODIMENTS

The above and other features of the inventive concept will be more clearly understood by describing in detail exemplary embodiments thereof with reference to the accompanying drawings.

Hereinafter, in the specification (and not necessarily in the claims), two directions parallel or substantially parallel to an upper surface of a substrate and crossing each other may be defined as first and second directions D1 and D2, respectively, and a direction perpendicular or substantially perpendicular to the upper surface of the substrate may be defined as a third direction D3. In example embodiments, the first and second directions D1 and D2 may be perpendicular or substantially perpendicular to each other.

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred).

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

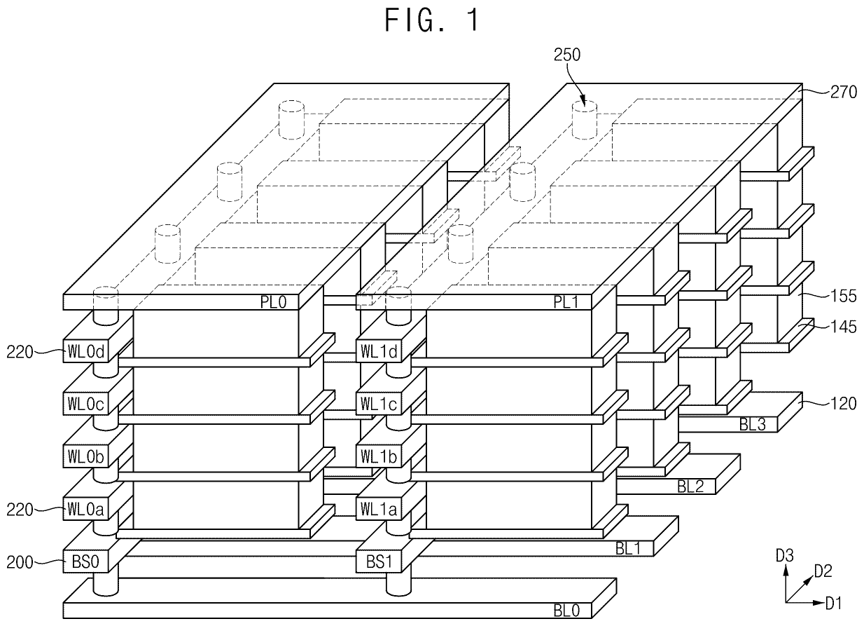

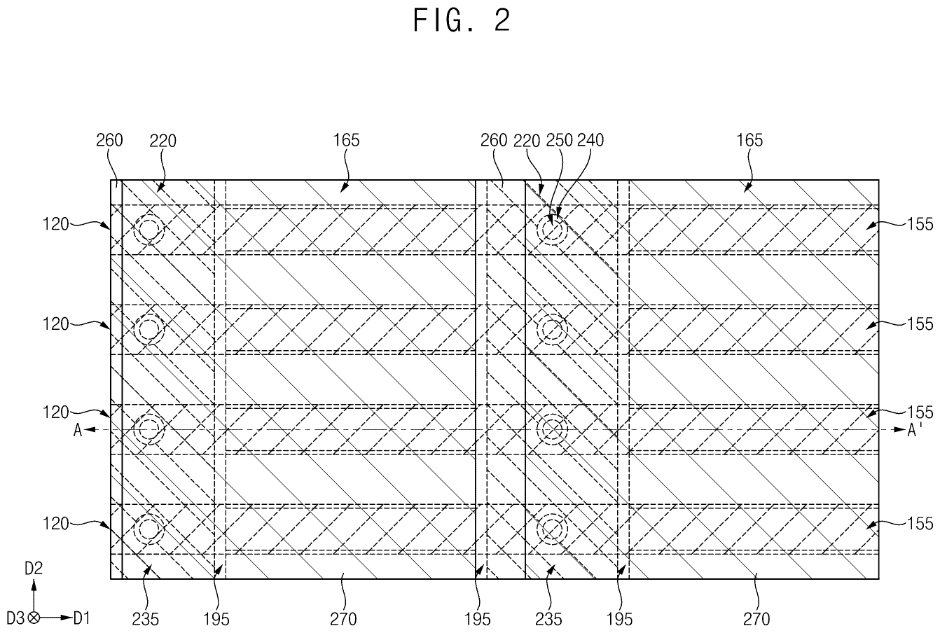

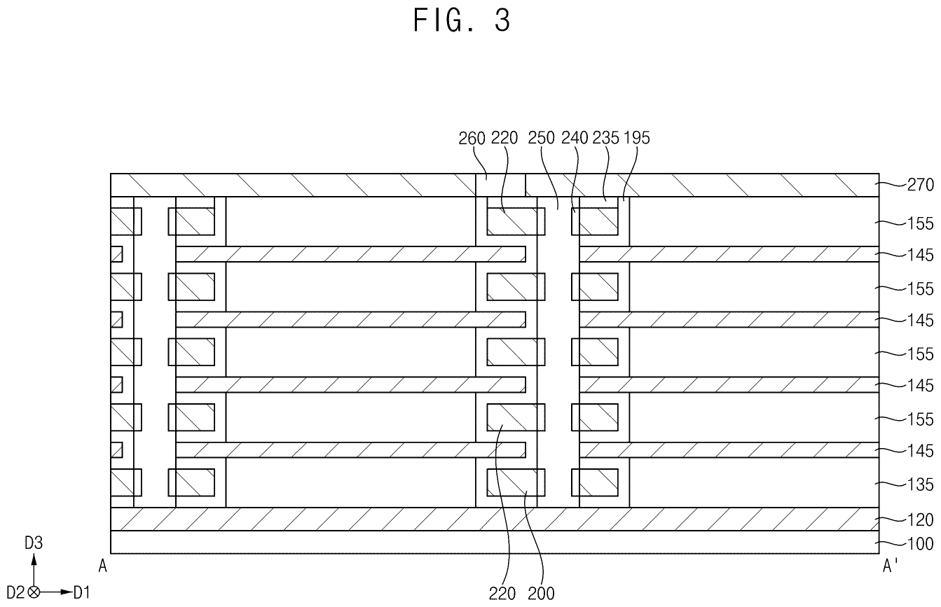

FIGS. 1 to 3 are a perspective view, a plan view and a cross-sectional view, respectively, illustrating a 3D ferroelectric random access memory (FeRAM) device in accordance with example embodiments. FIG. 3 is a cross-sectional view taken along line A-A′ of FIG. 2. Some elements of the 3D FeRAM device are not shown in FIG. 1 in order to avoid the complexity of the drawing.

Referring to FIGS. 1 to 3, the 3D FeRAM device may include a bit line 120, first and second conductive patterns 200 and 220, a gate insulation pattern 240, a channel 250, a capacitor electrode 145, a ferroelectric pattern 155 and a plate line 270 on a substrate 100.

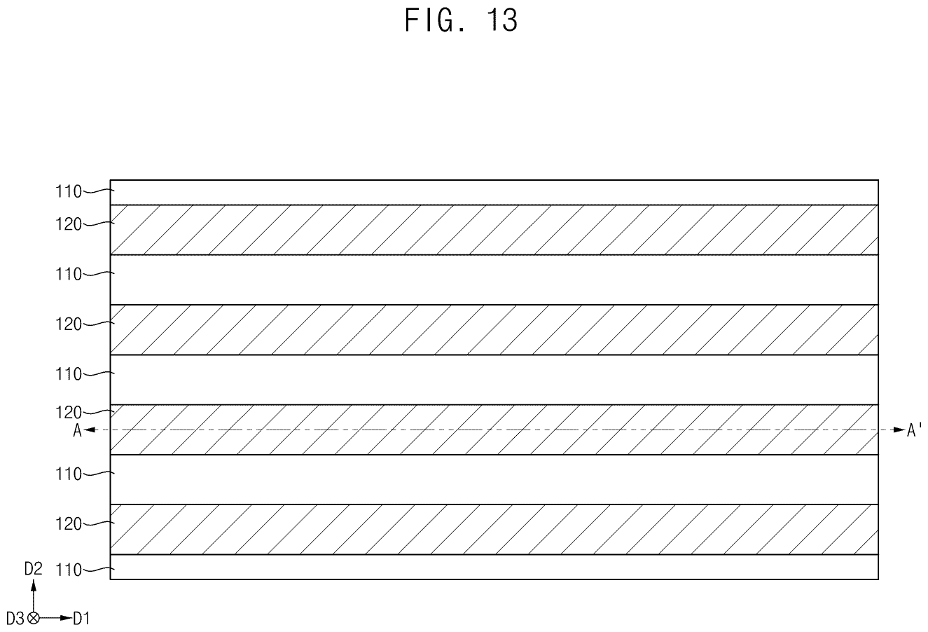

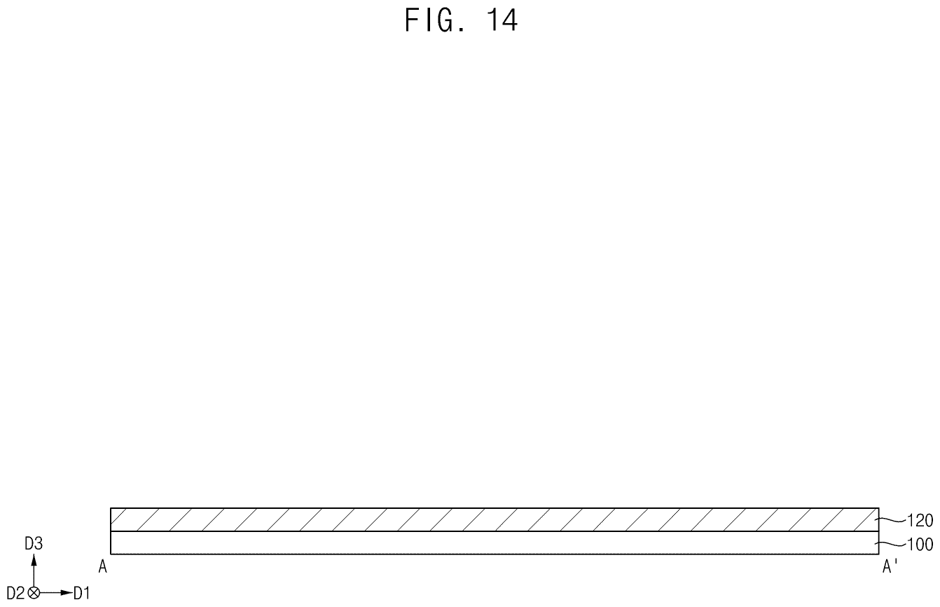

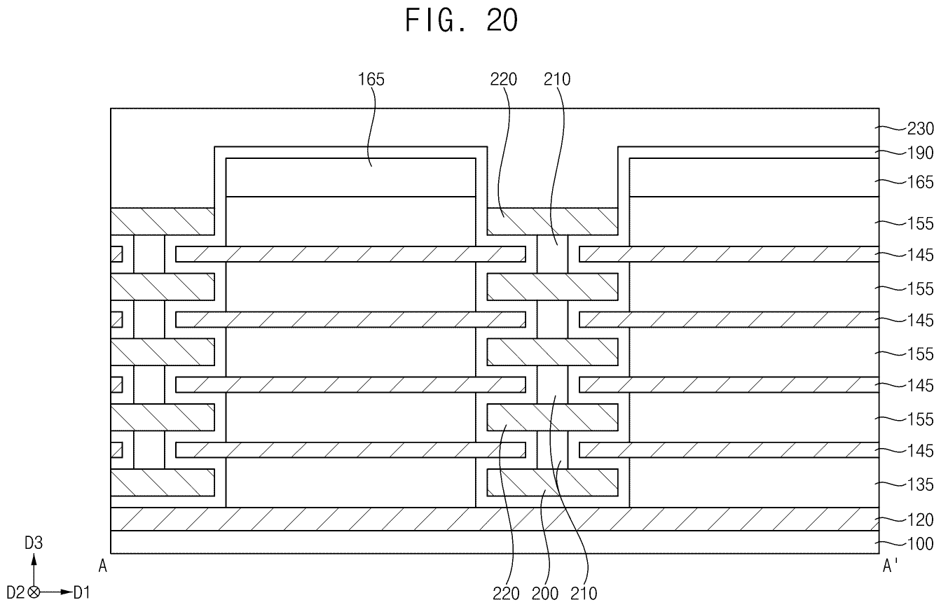

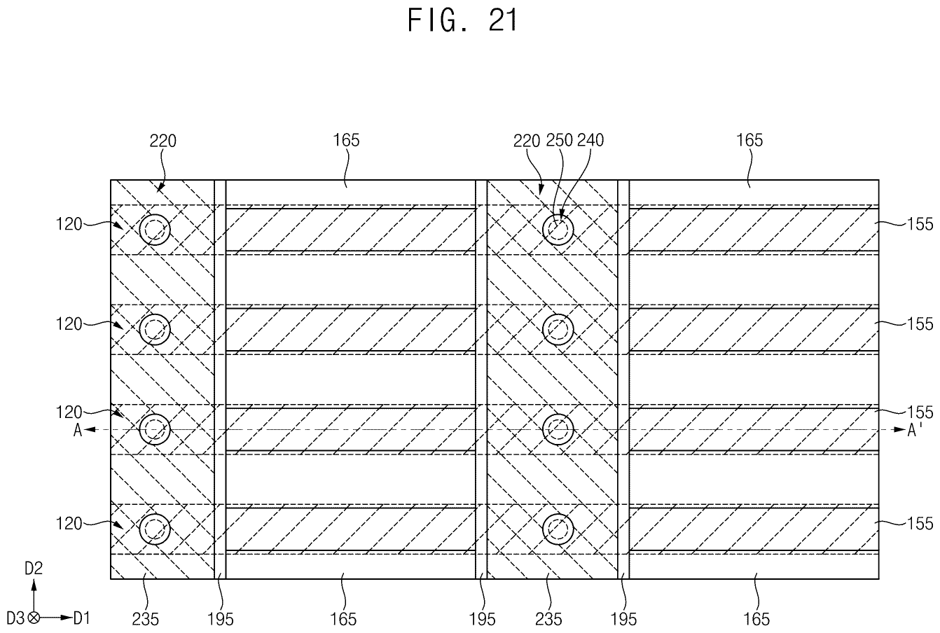

The 3D FeRAM device may further include a first insulation layer 110 (refer to FIG. 13), a seventh insulation layer 260, second to fourth insulation patterns 135, 165 and 195, a fifth insulation pattern 210 (refer to FIG. 20) and a sixth insulation pattern 235.

The substrate 100 may include, e.g., an insulating material or a semiconductor material.

The first insulation layer 110 may be disposed on the substrate 100, and the bit line 120 may be disposed on the substrate 100 and may extend through the first insulation layer 110. In example embodiments, the bit line 120 may extend lengthwise in the first direction D1, and a plurality of bit lines 120 may be spaced apart from each other in the second direction D2. Thus, the first insulation layer 110 and the bit line 120, each of which may extend lengthwise in the first direction D1, and portions/patterns of the first insulation layer 110 extending lengthwise in the first direction and the plurality of the bit lines 120 may be alternately and repeatedly disposed/arranged in the second direction D2 on the substrate 100.

Each of the first and second conductive patterns 200 and 220 may be disposed on the bit line 120 and the first insulation layer 110, and may extend, e.g., lengthwise, in the second direction D2. A plurality of first conductive patterns 200 may be spaced apart from each other in the first direction D1, and a plurality of second conductive patterns 220 may be spaced apart from each other in the first direction D1. In example embodiments, the first conductive pattern 200 may serve as a block selection line of the 3D FeRAM device, and the second conductive pattern 220 may serve as a word line of the 3D FeRAM device. A plurality of second conductive patterns 220 may be spaced apart from each other in the third direction D3 on each of the first conductive patterns 200.

The fifth insulation pattern 210 may be disposed between the first conductive pattern 200 and a lowermost one of the second conductive patterns 220 and between the second conductive patterns 220, and may contact the first and second conductive patterns 200 and 220. In example embodiments, the fifth insulation pattern 210 may contact an upper surface and/or a lower surface of a central portion in the first direction D1 of the first and second conductive patterns 200 and 220.

The sixth insulation pattern 235 may contact an upper surface of an uppermost one of the second conductive patterns 220, and may extend lengthwise in the second direction D2.

The fourth insulation pattern 195 may be disposed on the bit line 120 and the first insulation layer 110, and may extend lengthwise in the second direction D2. A plurality of fourth insulation patterns 195 may be spaced apart from each other in the first direction D1. Each of the fourth insulation patterns 195 may contact upper surfaces of the bit lines 120 and the first insulation layer 110, lower and upper surfaces and sidewalls in the first direction D1 of opposite edge portions in the first direction D1 of each of the first and second conductive patterns 200 and 220, opposite sidewalls in the first direction D1 of the fifth insulation pattern 210 and opposite sidewalls in the first direction D1 of the sixth insulation pattern 235.

The channel 250 may be disposed in a fourth opening 920 extending through the first and second conductive patterns 200 and 220 and the fourth and fifth insulation patterns 195 and 210 and exposing an upper surface of the bit line 120, and may have a shape of a pillar extending lengthwise in the third direction D3. Thus, each of the first and second conductive patterns 200 and 220 may surround the channel 250. The channel 250 may have a shape of, e.g., a circle, an ellipse, a polygon, a polygon with rounded corners, etc., in a plan view.

In example embodiments, the gate insulation pattern 240 may be disposed between each of the first and second conductive patterns 200 and 220 and the channel 250. For example, a second recess may be formed on a sidewall of a portion of the channel 250 facing each of the first and second conductive patterns 200 and 220, and the gate insulation pattern 240 may be disposed in the second recess. Thus, the gate insulation pattern 240 may have a shape of a ring surrounding the sidewall of the channel 250. The gate insulation pattern 240 may include an oxide, e.g., silicon oxide.

In example embodiments, a plurality of channels 250 may be spaced apart from each other in the first direction D1 on each of the bit lines 120, and thus may be disposed/arranged in each of the first and second directions D1 and D2. For example, the plurality of channels 250 may be spaced apart from each other in the first direction D1 and in the second direction D2.

The channel 250 may include, e.g., polysilicon.

The second insulation pattern 135 may be disposed on each of the bit lines 120, and a capacitor structure including capacitor electrodes 145 and ferroelectric patterns 155 alternately and repeatedly stacked in the third direction D3 may be formed on the second insulation pattern 135. The second insulation pattern 135 and the capacitor structure may collectively form a stack structure. The stack structure may extend to a given length in the first direction D1 on each of the bit lines 120, and a plurality of stack structures may be spaced apart from each other in the first direction D1. Thus, a plurality of stack structures may be spaced apart from each other in each of the first and second directions D1 and D2.

FIG. 2 shows that a width in the second direction D2 of the stack structure is less than a width in the second direction D2 of the bit line 120, however, the inventive concept is not limited thereto.

The second insulation pattern 135 may contact an upper surface of the bit line 120, a sidewall in the first direction D1 of the fourth insulation pattern 195 and a lower surface of a lowermost one of the capacitor electrodes 145.

The ferroelectric patterns 155 may be disposed between and contact capacitor electrodes 145 neighboring in the third direction D3, and an uppermost one of the ferroelectric patterns 155 may be disposed between and contact an uppermost one of the capacitor electrodes 145 and the plate line 270.

In example embodiments, a length in the first direction D1 of the ferroelectric patterns 155 may be substantially the same as a length in the first direction D1 of the second insulation patterns 135, and sidewalls in the first direction D1 of the ferroelectric patterns 155 may be aligned in the third direction D3 with sidewalls in the first direction D1 of the second insulation patterns 135. For example, the side walls of the ferroelectric patterns 155 may vertically overlap the sidewalls of the second insulation patterns 135.

The ferroelectric patterns 155 may include, e.g., hafnium oxide doped with, e.g., zirconium (Zr), silicon (Si), aluminum (Al), yttrium (Y), gadolinium (Gd), lanthanum (La), scandium (Sc), strontium (Sr), etc.

In example embodiments, each of opposite ends in the first direction D1 of the capacitor electrode 145 may protrude in the first direction D1 from opposite sidewalls in the first direction D1 of each of the ferroelectric patterns 155 and the second insulation pattern 135, and thus a length in the first direction D1 of the capacitor electrode 145 may be greater than the length in the first direction D1 of each of the ferroelectric patterns 155 and the second insulation pattern 135.

In example embodiments, lower and upper surfaces and a sidewall in the first direction D1 of a first end in the first direction D1 of the capacitor electrode 145 may be covered by the fourth insulation pattern 195, and lower and upper surfaces of a second end in the first direction D1 of the capacitor electrode 145 may be covered by the fourth insulation pattern 195, however, a sidewall in the first direction D1 of the second end of the capacitor electrode 145 may not be covered by the fourth insulation pattern 195 but contact the sidewall of the channel 250.

In example embodiments, a thickness in the third direction D3 of each of the ferroelectric patterns 155 may be greater than a thickness in the third direction D3 of a corresponding one of the second conductive patterns 220. Thus, an upper surface of the second conductive pattern 220 may be lower than an upper surface of a corresponding one of the ferroelectric patterns 155, and a lower surface of the second conductive pattern 220 may be higher than a lower surface of the corresponding one of the ferroelectric patterns 155. For example, the corresponding ones between the second conductive patterns 220 and the ferroelectric patterns 155 may be overlapping ones with each other in the first direction.

Likewise, a thickness in the third direction D3 of the second insulation pattern 135 may be greater than a thickness in the third direction D3 of a corresponding one of the first conductive patterns 200. Thus, an upper surface of the first conductive pattern 200 may be lower than an upper surface of a corresponding one of the second insulation pattern 135, and a lower surface of the first conductive pattern 200 may be higher than a lower surface of the corresponding one of the second insulation pattern 135. For example, the corresponding first conductive pattern 200 to the second insulation pattern 135 may be a closest first conductive pattern 200 to the second insulation pattern 135.

Accordingly, the first and second conductive patterns 200 and 220 may overlap the second insulation pattern 135 and the ferroelectric pattern 155, respectively, in the first direction D1.

The third insulation pattern 165 may be disposed on the bit line 120 (e.g., on an edge portion of the bit line 120) and the first insulation layer 110, and may be disposed between stack structures neighboring in the second direction D2 and contact sidewalls in the second direction D2 of the stack structures. Additionally, the third insulation pattern 165 may contact an outer sidewall in the first direction D1 of the fourth insulation pattern 195. In an example embodiment, a length in the first direction D1 of the third insulation pattern 165 may be substantially the same as the length in the first direction D1 of each of the ferroelectric pattern 155 and the second insulation pattern 135.

The plate line 270 may be disposed on and contact upper surfaces of the stack structures, the third, fourth and sixth insulation patterns 165, 195 and 235 and the channel 250. In example embodiments, the plate line 270 may extend lengthwise in the second direction D2 to contact the upper surfaces of the channels 250 disposed/arranged in the second direction D2, and a plurality of plate lines 270 may be spaced apart from each other in the first direction D1.

The seventh insulation layer 260 may be disposed on the fourth and sixth insulation patterns 195 and 235, and may separate plate lines 270 neighboring in the first direction D1 from each other. For example, the seventh insulation layer 260 may be placed between the plate lines 270 at the same level as the plate lines 270 such that the seventh insulation layer 260 overlaps the plate lines 270 in the first direction D1 and/or in the second direction D2.

Each of the bit lines 120, the first and second conductive patterns 200 and 220, the capacitor electrodes 145 and the plate lines 270 may include a conductive material, e.g., a metal, a metal nitride, a metal silicide, etc. Each of the first and seventh insulation layers 110 and 260 and the second to sixth insulation patterns 135, 165, 195, 210 and 235 may include an oxide, e.g., silicon oxide or an insulating nitride, e.g., silicon nitride. Some of the first and seventh insulation layers 110 and 260 and the second to sixth insulation patterns 135, 165, 195, 210 and 235 may include the same or substantially the same material so as to be merged/integrated with each other, e.g., without clear boundaries between the patterns/layers.

In the 3D FeRAM device, a pair of capacitor electrodes 145 neighboring in the third direction D3 and the ferroelectric pattern 155 therebetween may collectively form a ferroelectric capacitor. A plurality of ferroelectric capacitors may be connected in series in the third direction D3, and two ferroelectric capacitors neighboring in the third direction D3 may share a capacitor electrode 145. Thus, the integration degree of the 3D FeRAM device may be enhanced.

An uppermost one of the capacitor electrodes 145 and an uppermost one of the ferroelectric pattern 155 together with the plate line 270 may collectively form a ferroelectric capacitor, however, the inventive concept is not limited thereto. For example, an additional capacitor electrode 145 may be disposed between the uppermost one of the ferroelectric patterns 155 and the plate line 270, and the additional capacitor electrode 145, the uppermost one of the ferroelectric patterns 155 and the plate line 270 may collectively form a ferroelectric capacitor.

The bit lines 120 may extend lengthwise in the first direction D1 on the substrate 100, and may include, e.g., BL0, BL1, BL2, BL3, etc., spaced apart from each other in the second direction D2. Additionally, block selection lines 200 may extend lengthwise in the second direction D2 on the bit lines 120, and may include, e.g., block selection lines BS1, BS2, etc., spaced apart from each other in the first direction D1.

Further, the word line 220 may extend lengthwise in the second direction D2 on each of the block selection lines 200, and a plurality of word lines 220 may be spaced apart from each other in the third direction D3 on each of the block selection lines 200. As the plurality of block selection lines 200 are disposed/arranged in the first direction D1, for example, the word lines 220 disposed on a block selection line BS0 may include, e.g., WL0a, WL0b, WL0c, WL0d, etc., stacked in the third direction D3, and the word lines 220 disposed on the block selection line BS1 may include, e.g., WL1a, WL1b, WL1c, WL1d, etc., stacked in the third direction D3.

The plate lines 270 may extend lengthwise in the second direction D2 on the respective word lines 220, and may include, e.g., plate lines PL0, PL1, etc., disposed/arranged in the first direction D1.

The channels 250 may extend lengthwise in the third direction D3 through the word lines 220 and the block selection lines 220, and may contact upper surfaces of the bit lines 120 and lower surfaces of the plate lines 270 to be electrically connected thereto. Thus, each of the word lines 220 or the block selection line 200, a portion of the channel 250 corresponding thereto in a horizontal direction, and the gate insulation pattern 240 between the corresponding one of the word lines 220 or the block selection line 200 and the portion of the channel 250 may collectively form a transistor. The transistor and the ferroelectric capacitor at the same level as the transistor may collectively form a memory cell.

As a result, the memory cells may be arranged in a horizontal direction, e.g., in the first and/or second directions D1 and/or D2 on the substrate 100, and may also be arranged in the vertical direction, that is, in the third direction D3. Memory cells arranged in the third direction D3 may collectively form a memory cell chain, and memory cell chains arranged in the second direction D2 may collectively form a memory block or a memory cell block.

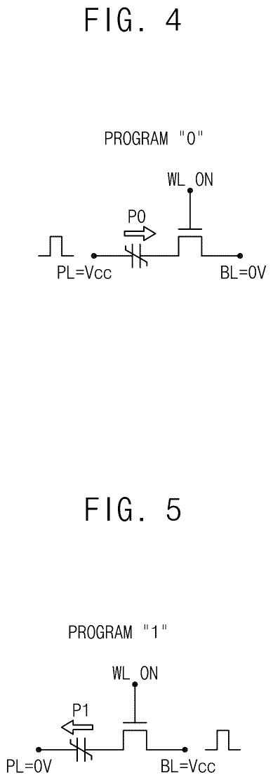

FIGS. 4 and 5 are circuit diagrams illustrating a program operation of each memory cell included in a ferroelectric memory device.

Referring to FIG. 4, when a word line WL is ON and 0V is applied to a bit line BL, if Vcc is applied to a plate line PL, then an electric field in a first direction may be applied to a ferroelectric capacitor, and the ferroelectric capacitor may be in a first polarization state P0 by the electric field so that “0” may be programmed.

Even though the bit line BL and the plate line PL are maintained at 0V, the ferroelectric capacitor may be maintained in the first polarization state P0.

Referring to FIG. 5, when the word line WL is ON and 0V is applied to the plate line PL, if Vcc is applied to the bit line BL, then an electric field in a direction opposite to the first direction may be applied to the ferroelectric capacitor, and the ferroelectric capacitor may be changed to a second polarization state P1 of which a direction is opposite to that of the first polarization state P0 by the electric field so that “1” may be programmed.

Even though the plate line PL and the bit line BL are maintained at 0V, the ferroelectric capacitor may be maintained in the second polarization state P1.

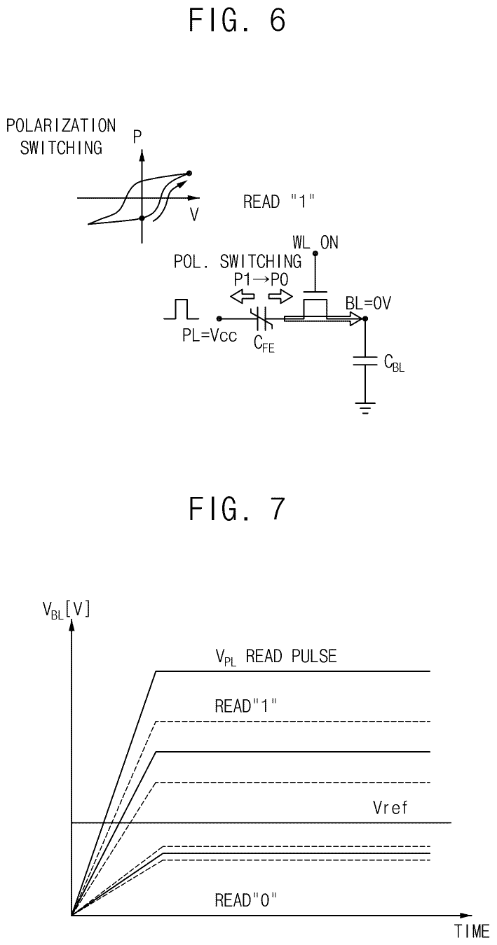

FIGS. 6 to 8 show circuit diagrams, hysteresis curves and a voltage graph for explaining a read operation of each memory cell included in a ferroelectric memory device.

Referring to FIGS. 6 and 7, when “0” is programmed, the word line WL is ON and 0V is applied to the bit line BL, if Vcc is applied to the plate line PL, then an electric field having the same direction as that of the previous electric field may be applied to the ferroelectric capacitor, so that the first polarization state P0 may not be switched but maintained.

A first bit line voltage V⁰_{BL} may be detected in the bit line BL.

$${V}_{B L}^{0} = \frac{{C}_{F E}}{{C}_{F E} + {C}_{B L}} \times {V}_{P L}$$

(C_{FE} is a capacitance of the ferroelectric capacitor, C_{BL} is a capacitance between the bit line and the ground, and V_{PL} is a plate line voltage.)

The first bit line voltage V¹_{BL} is less than a reference voltage V_{ref}, so that data “0” may be read.

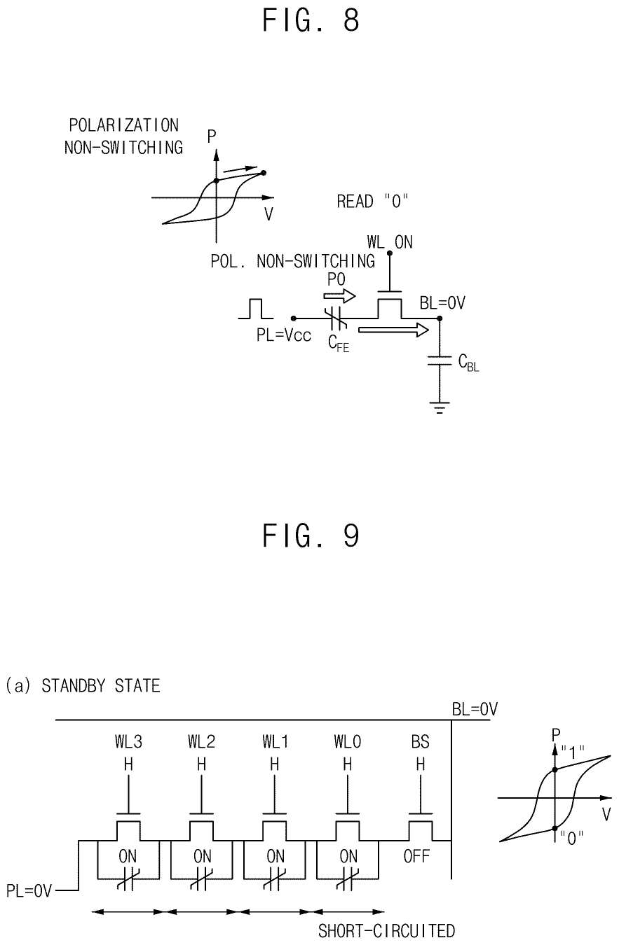

Referring to FIGS. 7 and 8, when “1” is programmed, the word line WL is ON and 0V is applied to the bit line BL, if Vcc is applied to the plate line PL, then an electric field having a direction opposite to that of the previous electric field may be applied to the ferroelectric capacitor, so that the first polarization state P0 may be switched to the second polarization state P1.

A second bit line voltage V¹_{BL} may be detected in the bit line BL.

$${V}_{B L}^{1} = \frac{{C}_{F E}}{{C}_{F E} + {C}_{B L}} \times {V}_{P L} + \frac{2 {P}_{r} \times {A}_{F E}}{{C}_{F E} + {C}_{B L}}$$

(Pᵣ is a remanent polarization, and A_{FE} is a cross-sectional area of the ferroelectric capacitor.)

The second bit line voltage V¹_{BL} is equal to or greater than the reference voltage V_{ref}, so that data “1” may be read.

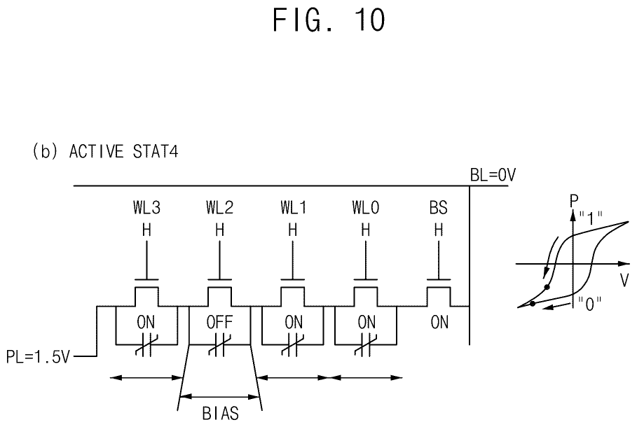

FIGS. 9 and 10 show circuit diagrams and hysteresis curves for explaining a standby state and an active state of a chain memory cell string including the ferroelectric capacitor chain when ferroelectric capacitors are connected to each other in series to form a ferroelectric capacitor chain.

Referring to FIG. 9, when word lines WL0, WL1, WL2 and WL3 electrically connected to ferroelectric capacitors, respectively, are ON, a block selection line BS electrically connected to the chain memory cell string is OFF, and a plate line PL and a bit line BL electrically connected to the chain memory cell string are at 0V, the chain memory cell string is in a standby state.

The ferroelectric capacitors are all short, and thus data stored in each memory cell may be protected so that initial data “0” or “1” may be maintained.

Referring to FIG. 10, when the word line WL2 among the word lines WL0, WL1, WL2 and WL3 electrically connected to ferroelectric capacitors, respectively, is OFF, and given voltages are applied to the plate line PL and the bit line BL, respectively, (1.5V is applied to the plate line PL in FIG. 10), a bias voltage is applied to only a ferroelectric capacitor connected to the word line WL2 so that the ferroelectric capacitor is in an active state.

According to a difference of respective voltages applied to the plate line PL and the bit line BL, the polarization state of the ferroelectric capacitor may be switched or maintained.

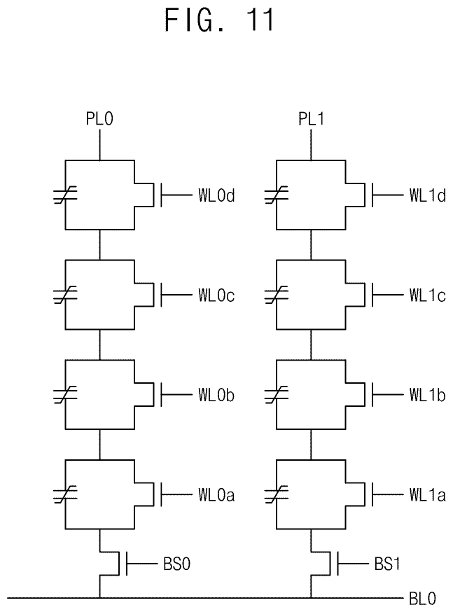

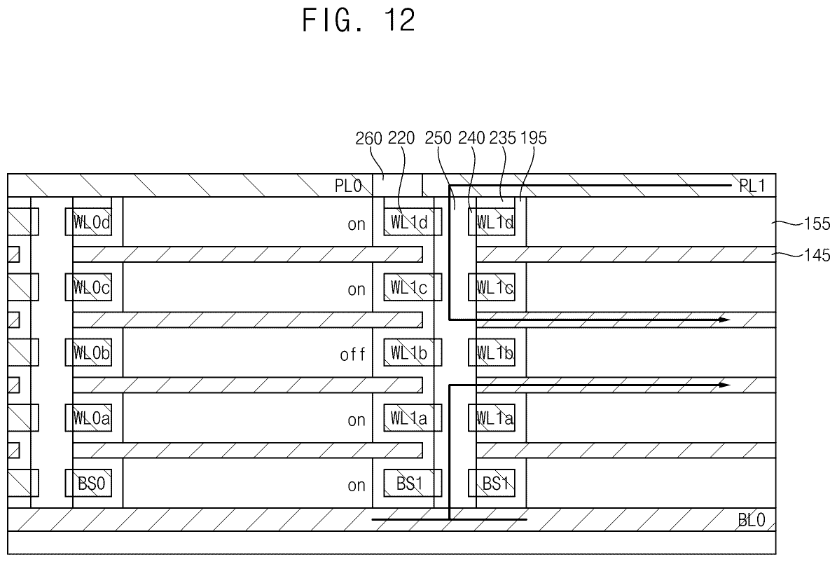

FIG. 11 is a circuit diagram illustrating an electrical connection of memory cells disposed between a bit line and a plate line in a 3D FeRAM device in accordance with example embodiments, and FIG. 12 is a drawing illustrating an operation of the memory cells.

Referring to FIG. 11, for example, block selection lines BS0, BS1, etc., may be connected to a bit line BL0, for example, word lines WL0a, WL0b, WL0c and WL0d, etc., may be connected to the block selection line BS0, and for example, word lines WL1a, WL1b, WL1c, WL1d, etc., may be connected to the block selection line BS1.

If an electrical signal is applied to the bit line BL0, the electrical signal may be transferred to word lines e.g., the word lines WL1a, WL1b, WL1c, WL1d, etc., that are connected to one of the block selection lines that is ON among the block selection lines, e.g., the block selection line BS1, and the electrical signal may not be transferred to word lines e.g., the word lines WL0a, WL0b, WL0c, WL0d, etc., that are connected to one of the block selection lines that is OFF among the block selection lines, e.g., the block selection line BS0.

A plate line PL0 among the plate lines may be connected to a word line WL0d that is an uppermost one of the word lines connected to the block selection line BS0, and a plate line PL1 among the plate lines may be connected to a word line WL1d that is an uppermost one of the word lines connected to the block selection line BS1.

Further, ferroelectric capacitors may be connected to the word lines WL0a, WL0b, WL0c, WL0d, etc., respectively, disposed on the block selection line BS0 in the third direction D3, which may be connected to each other in series to form a chain. Likewise, ferroelectric capacitors may be connected to the word lines WL1a, WL1b, WL1c, WL1d, etc., respectively, disposed on the block selection line BS1 in the third direction D3, which may be connected to each other in series to form a chain.

Like the bit line BL0, the block selection lines BS1, BS2, etc., may also be connected to the bit line BL1.

Referring to FIG. 12, if a memory cell including, e.g., the word line WL1b is accessed among the memory cells, the block selection line BS1 may be ON, the word line WL1b among the word lines connected to the block selection line BS1 may be OFF, and other word lines WL1a, WL1c, WL1d, etc., may be ON.

During a read operation of data written in the memory cell, the bit lines BL0, BL1, etc., may be OFF and the plate line PL1 may be ON. However, block selection lines not connected to the word line WL1b, e.g., the block selection line BS0 may be OFF, and the word lines WL0a, WL0b, WL0c, WL0d, etc., connected to the block selection line BS0 may be ON, and thus memory cells connected to the word lines WL0a, WL0b, WL0c, WL0d, etc., may be in a standby state so as to protect the data stored in the ferroelectric capacitor.

During a writing operation into the memory cell, the bit lines BL0, BL1, etc., may be OFF and the plate line PL1 may be ON, or the bit lines BL0, BL1, etc., may be ON and the plate line PL1 may be OFF.

FIGS. 13 to 22 are plan views and cross-sectional views illustrating a method of manufacturing a 3D FeRAM device in accordance with example embodiments. Particularly, FIGS. 13, 16, 18 and 21 are the plan views, and FIGS. 14-15, 17, 19-20 and 22 are cross-sectional views taken along lines A-A′ of corresponding plan views, respectively.

Referring to FIGS. 13 and 14, a first insulation layer 110 may be formed on a substrate 100, and a bit line 120 may be formed through the first insulation layer 110 on the substrate 100, e.g., after removing a portion of the first insulation layer 110.

In example embodiments, the bit line 120 may extend lengthwise in the first direction D1, and a plurality of bit lines 120 may be spaced apart from each other in the second direction D2.

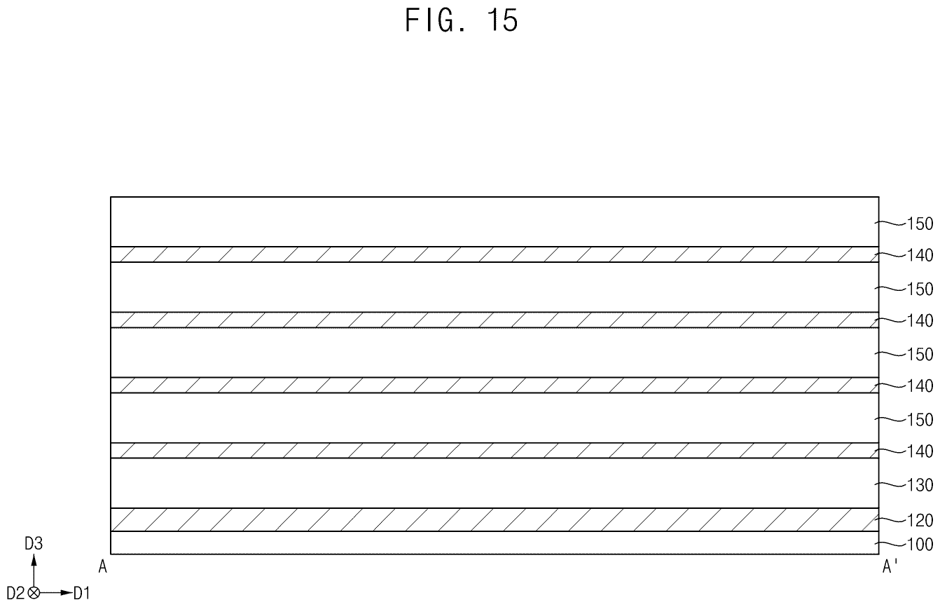

Referring to FIG. 15, a second insulation layer 130 may be formed on the first insulation layer 110 and the bit line 120, and capacitor electrode layers 140 and ferroelectric layers 150 may be alternately and repeatedly stacked on the second insulation layer 130 in the third direction D3.

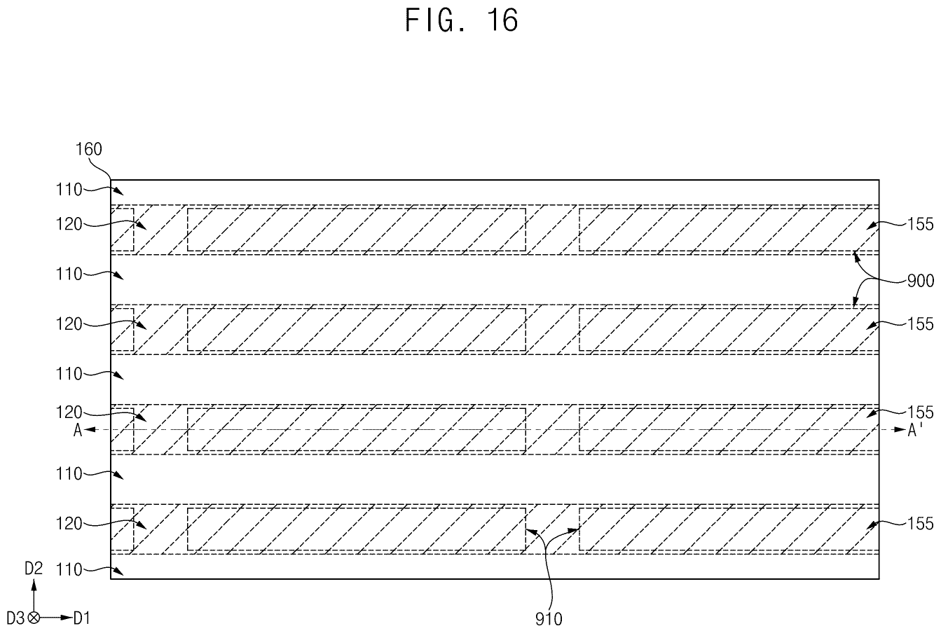

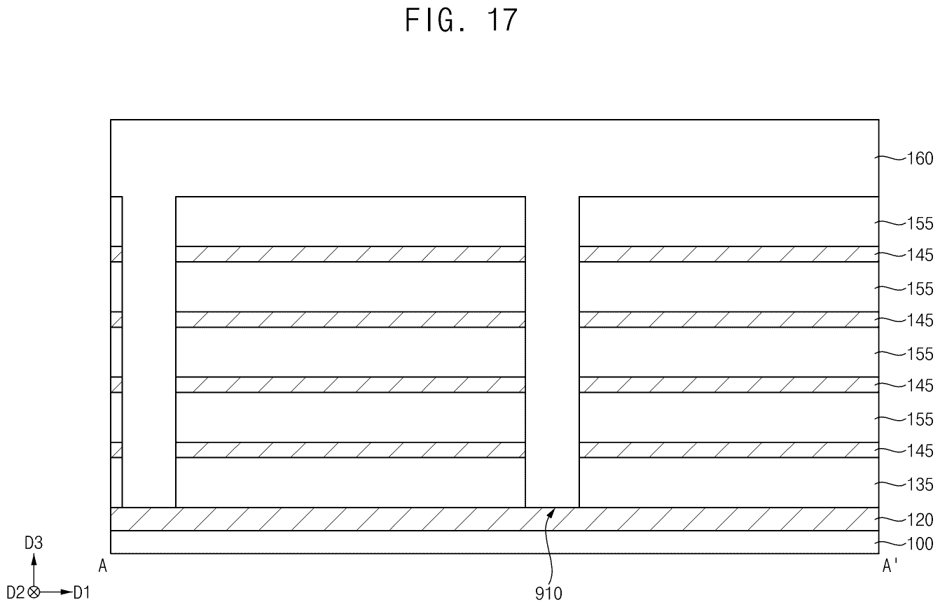

Referring to FIGS. 16 and 17, a dry etching process may be performed on the ferroelectric layers 150, the capacitor electrode layers 140 and the second insulation layer 130 to form first and second openings 900 and 910 exposing upper surfaces of the first insulation layer 110 and the bit lines 120, and a ferroelectric pattern 155, a capacitor electrode 145 and a second insulation pattern 135 may be formed.

In example embodiments, the first opening 900 may extend, e.g., lengthwise, in the first direction D1, and may expose the upper surface of the first insulation layer 110 and upper surfaces of opposite edge portions in the second direction D2 of the bit line 120. A plurality of first openings 900 may be spaced apart from each other in the second direction D2. Additionally, the second opening 910 may extend, e.g., lengthwise, in the second direction D2, and may expose the upper surfaces of the first insulation layer 110 and the bit lines 120. A plurality of second openings 910 may be spaced apart from each other in the first direction D1. The second opening 910 may cross the first opening 900 and may be connected thereto.

As the first and second openings 900 and 910 are formed, a plurality of ferroelectric patterns 155 may be formed to be spaced apart from each other in each of the first and second directions D1 and D2, a plurality of capacitor electrodes 145 may be formed to be spaced apart from each other in each of the first and second directions D1 and D2, and a plurality of second insulation patterns 135 may be formed to be spaced apart from each other in each of the first and second directions D1 and D2. Additionally, the capacitor electrode 145 and the ferroelectric pattern 155 may be alternately and repeatedly stacked in the third direction D3 on the second insulation pattern 135.

In example embodiments, the ferroelectric patterns 155, the capacitor electrodes 145 and the second insulation pattern 135 stacked in the third direction D3 may collectively form a stack structure, and a plurality of stack structures may be spaced apart from each other in the first direction D1 on each of the bit lines 120. FIG. 16 shows that a width in the second direction D2 of the stack structure is smaller than a width in the second direction D2 of a corresponding one of the bit lines 120, however, the inventive concept is not limited thereto.

In each stack structure, the capacitor electrodes 145 and the ferroelectric patterns 155 alternately and repeatedly stacked in the third direction D3 may collectively form a capacitor structure.

A third insulation layer 160 may be formed on the first insulation layer 110, the bit lines 120 and the stack structures to fill the first and second openings 900 and 910. The third insulation layer 160 may include a first portion disposed in the first openings 900 and extending, e.g., lengthwise, in the first direction D1, a second portion disposed in the second openings 910 and extending, e.g., lengthwise, in the second direction D2 to cross the first portion, and a third portion on upper surfaces of the stack structures.

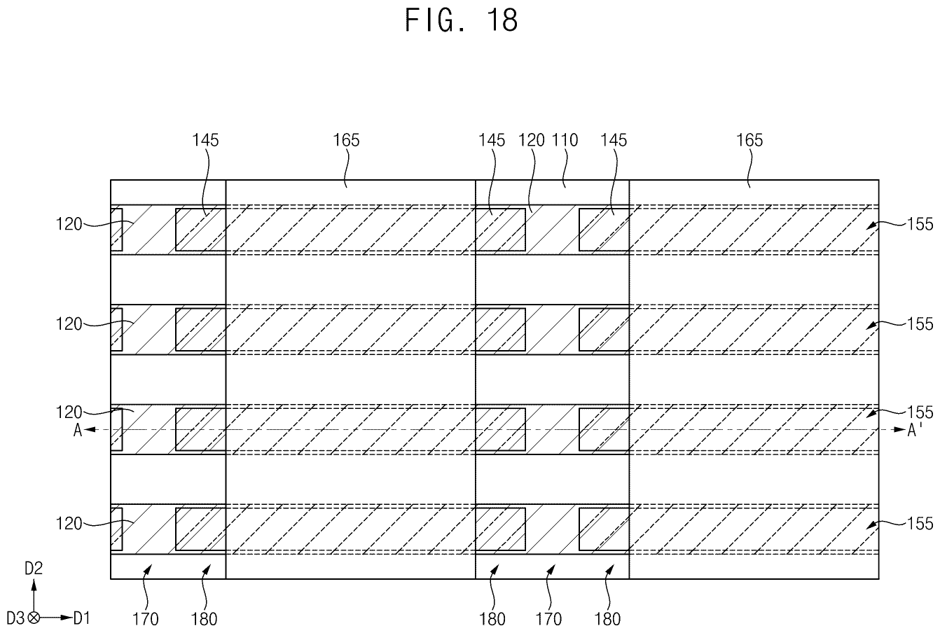

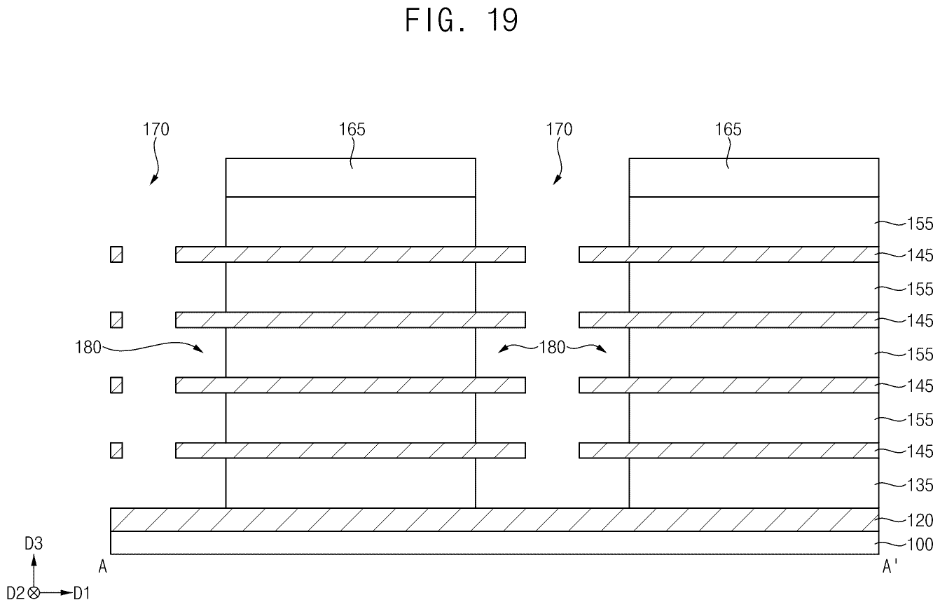

Referring to FIGS. 18 and 19, a dry etching process may be performed on the third insulation layer 160 to form a third opening 170 exposing upper surfaces of the first insulation layer 110 and the bit line 120.

In example embodiments, the third opening 170 may extend, e.g., lengthwise, through the second portion of the third insulation layer 160 in the second direction D2, and a plurality of third openings 170 may be spaced apart from each other in the first direction D1. By the dry etching process, the second portion of the third insulation layer 160 may be removed, and the first and third portions may remain to be changed into or to form a third insulation pattern 165.

A wet etching process may be performed through the third opening 170, and thus a portions of the ferroelectric pattern 155, the second insulation pattern 135 and the third insulation pattern 165 that are adjacent to the third opening 170 in the first direction D1 may be removed to form a first recess 180 extending, e.g., lengthwise, in the second direction D2 to be connected to the third opening 170 between capacitor electrodes 145 neighboring in the third direction D3, between the bit line 120 and a lowermost one of the capacitor electrodes 145 and on an upper surface of an uppermost one of the capacitor electrodes 145.

Referring to FIG. 20, a fourth insulation layer 190 may be formed on the first insulation layer 110 and the bit line 120 to cover an inner wall of the third opening 170 and an inner wall of the first recess 180, a conductive layer may be formed on the fourth insulation layer 190 to fill the third opening 170 and the first recess 180, and, for example, a wet etching process may be performed on the conductive layer to form a first conductive pattern 200 in the first recess 180 between the bit line 120 and the lowermost one of the capacitor electrodes 145 and a portion of the third opening 170 at the same height as the first recess 180.

In example embodiments, the first conductive pattern 200 may extend lengthwise in the second direction D2, and a plurality of first conductive patterns 200 may be spaced apart from each other in the first direction D1.

A fifth insulation layer may be formed on the fourth insulation layer 190 and the first conductive pattern 200 to fill the third opening 170 and the first recess 180, and for example, a wet etching process may be performed on the fifth insulation layer to form a fifth insulation pattern 210 having an upper surface higher than an upper surface of the lowermost one of the capacitor electrodes 145. In example embodiments, the fifth insulation pattern 210 may extend, e.g., lengthwise, in the second direction D2, and a plurality of fifth insulation patterns 210 may be spaced apart from each other in the first direction D1.

Likewise, second conductive patterns 220 and fifth insulation patterns 210 sequentially stacked in the third direction D3 may be formed in the third opening 170 and the first recess 180 on the fifth insulation pattern 210, and a sixth insulation layer 230 may be formed on an uppermost one of the second conductive patterns 220 and the fourth insulation layer 190 to fill the third opening 170.

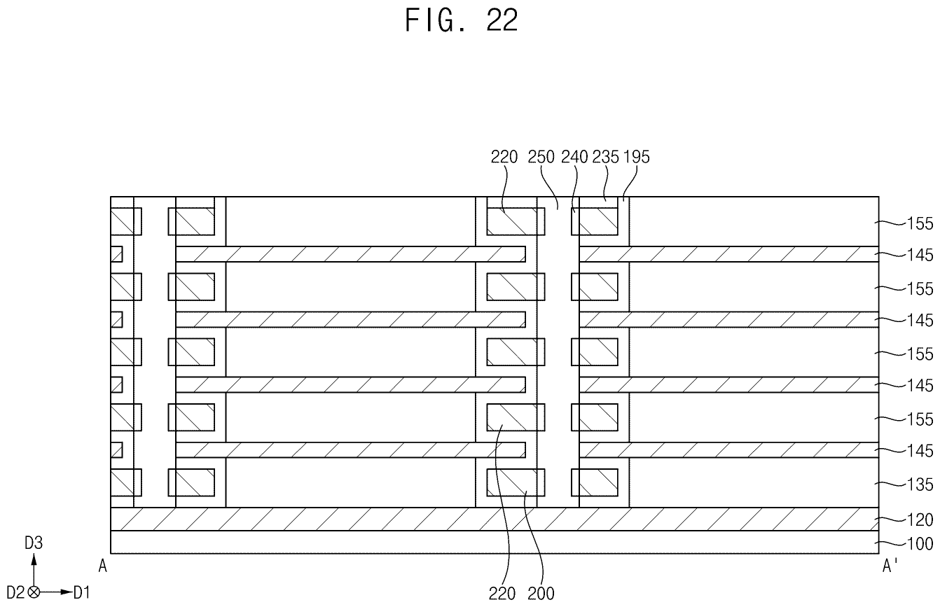

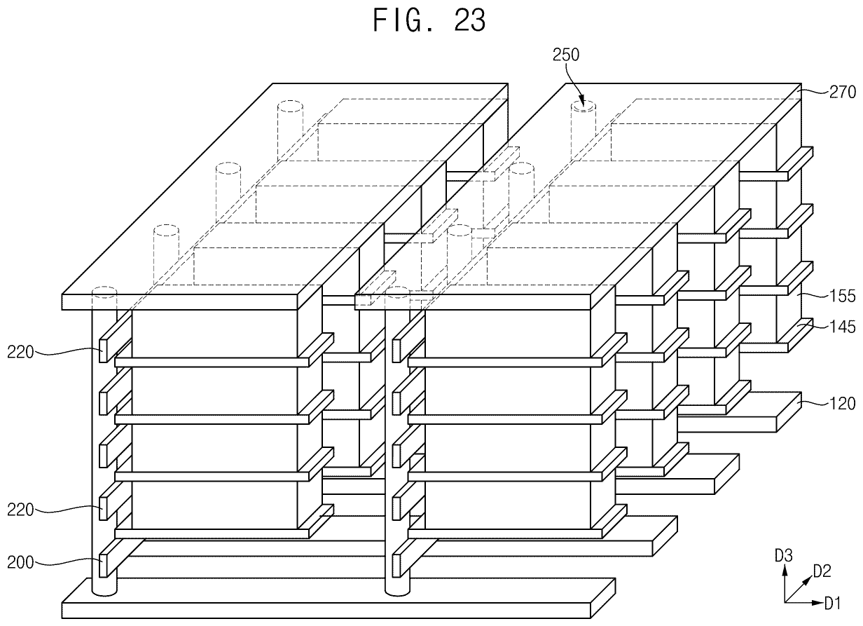

Referring to FIGS. 21 and 22, a dry etching process may be performed on the sixth insulation layer 230, the first and second conductive patterns 200 and 220, the fifth insulation pattern 210 and the fourth insulation layer 190 to form a fourth opening 920 exposing an upper surface of the bit line 120 and a sidewall in the first direction D1 of the capacitor electrode 145.

In example embodiments, the fourth opening 920 may be formed by etching the fifth insulation pattern 210 and a portion of the fourth insulation layer 190 at a side of the fifth insulation pattern 210 in the first direction D1, and thus sidewalls in the first direction D1 of the capacitor electrodes 145 at a first side of the fifth insulation pattern 210 in the first direction D1 may be exposed while sidewalls in the first direction D1 of the capacitor electrodes 145 at a second side of the fifth insulation pattern 210 in the first direction D1 may be covered by the fourth insulation layer 190 and not be exposed.

For example, a thermal oxidation process may be performed on sidewalls of the first and second conductive patterns 200 and 220 exposed by the fourth opening 920 to form a gate insulation pattern 240.

A channel layer may be formed on an upper surface of the bit line 120, the exposed sidewall of the capacitor electrode 145 and a surface of the gate insulation pattern 240 to fill the fourth opening 920, and a planarization process may be performed on the channel layer, the fourth insulation layer 190 and the third insulation pattern 165 until an upper surface of an uppermost one of the ferroelectric patterns 155 is exposed.

In example embodiments, a plurality of fourth openings 920 may be spaced apart from each other in each of the first and second directions D1 and D2.

In example embodiments, the planarization process may include or may be a chemical mechanical polishing (CMP) process and/or an etch back process.

By the planarization process, a channel 250 extending lengthwise in the third direction D3, and the gate insulation pattern 240 surrounding a sidewall of a portion of the channel 250 facing each of the first and second conductive patterns 200 and 220 in the horizontal direction may be formed in the fourth opening 920. For example, the fourth opening 920 may be filled with gate insulation patterns 240 and the channel 250. In example embodiments, a plurality of channels 250 may be spaced apart from each other in each of the first and second directions D1 and D2, and a plurality of gate insulation patterns 240 may be spaced apart from each other in each of the first and second directions D1 and D2. Additionally, a plurality of gate insulation patterns 240 may be spaced apart from each other in the third direction D3 on the sidewall of each of the channels 250.

By the planarization process, the fourth insulation layer 190 may be divided into a plurality of fourth insulation patterns 195. A portion of the third insulation pattern 165 on an upper surface of the stack structure may be removed, and a portion of the third insulation pattern 165 contacting upper surfaces of the first insulation layer 110 and the bit line 120 between neighboring stack structures in the second direction D2 may remain. The sixth insulation layer 230 may be transformed into a sixth insulation pattern 235 extending lengthwise in the second direction D2 on an upper surface of an uppermost one of the second conductive patterns 220.

Referring to FIGS. 1 to 3 again, a seventh insulation layer 260 may be formed on the stack structure, the third, fourth and sixth insulation patterns 165, 195 and 235 and the channel 250. After removing a portion of the seventh insulation layer 260, a plate line 270 may be formed in the removed portion of the seventh insulation layer 260 to contact an upper surface of the channel 250.

In example embodiments, the plate line 270 may extend lengthwise in the second direction D2 to contact upper surfaces of channels 250 disposed/arranged in the second direction D2, and a plurality of plate lines 270 may be spaced apart from each other in the first direction D1. Each of the plate lines 270 may also contact upper surfaces of the stack structure and the third, fourth and sixth insulation patterns 165, 195 and 235.

By the above processes, the fabrication of the 3D FeRAM device may be completed.

FIGS. 23 to 25 are views illustrating 3D FeRAM devices in accordance with example embodiments, which may correspond to FIG. 1.

These 3D FeRAM devices may be the same as or similar to that of FIGS. 1 to 3 except for block selection lines, word lines and plate lines, and thus repeated explanations are omitted herein.

Referring to FIG. 23, the channel 250 may not extend through each of the first and second conductive patterns 200 and 220, and each of the first and second conductive patterns 200 and 220 may not surround the channel 250 but may be disposed on a sidewall of the channel 250.

The gate insulation pattern 240 may be disposed between the channel 250 and each of the first and second conductive patterns 200 and 220.

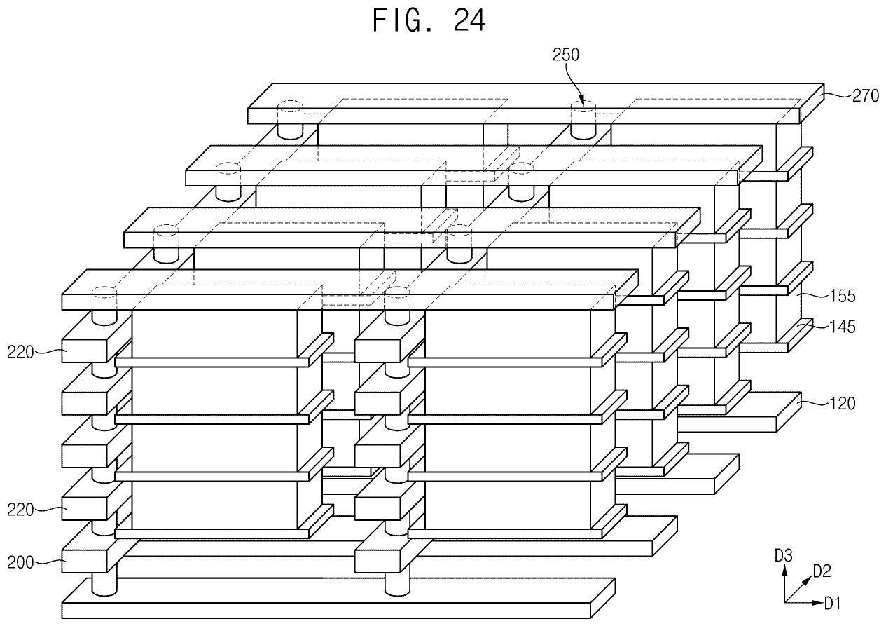

Referring to FIG. 24, the plate line 270 may extend lengthwise in the first direction D1, and a plurality of plate lines 270 may be spaced apart from each other in the second direction D2.

The plate line 270 may extend lengthwise in the first direction D1 as the bit line 120. In example embodiments, each plate line 270 may overlap a corresponding one of the bit lines 120 in the third direction D3.

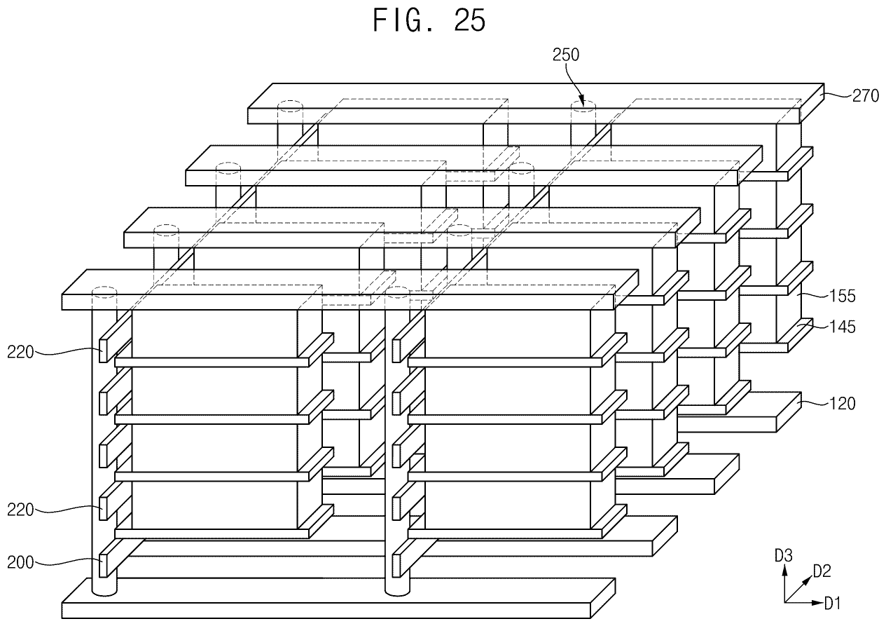

Referring to FIG. 25, the plate line 270 may extend lengthwise in the first direction D1 as that of FIG. 24. Additionally, the channel 250 may not extend through each of the first and second conductive patterns 200 and 220, and each of the first and second conductive patterns 200 and 220 may be disposed on the sidewall of the channel 250 as that of FIG. 23.

The gate insulation pattern 240 may be disposed between the channel 250 and each of the first and second conductive patterns 200 and 220.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While the inventive concept has been shown and described with reference to exemplary embodiments thereof, it will be apparent to those of ordinary skill in the art that various modifications in form and details may be made thereto without departing from the spirit and scope of the inventive concept.

What is claimed is:

1. A 3D FeRAM device, comprising:
bit lines on a substrate, each of the bit lines extending lengthwise in a first direction parallel to an upper surface of the substrate, and the bit lines being spaced apart from each other in a second direction parallel to the upper surface of the substrate and crossing the first direction;
block selection lines on the bit lines, each of the block selection lines extending lengthwise in the second direction, and the block selection lines being spaced apart from each other in the first direction;
a set of word lines on each of the block selection lines, each of the word lines for each set extending lengthwise in the second direction, and each set of the word lines including a plurality of word lines spaced apart from each other in a third direction perpendicular to the upper surface of the substrate;
channels spaced apart from each other in the first direction and in the second direction, each of the channels extending lengthwise in the third direction through one of the block selection lines and a corresponding set of the word lines arranged in the third direction on an upper surface of a corresponding one of the bit lines;
a plate line extending lengthwise in the second direction and contacting upper surfaces of the channels arranged in the second direction; and
capacitor structures spaced apart from each other in the first direction, each of the capacitor structures including capacitor electrodes and ferroelectric patterns alternately stacked in the third direction on a corresponding one of the bit lines,
wherein the capacitor electrodes of each of the capacitor structures contact and are electrically connected to a corresponding one of the channels.

2. The 3D FeRAM device of claim 1, wherein each of the word lines overlaps a corresponding one of the ferroelectric patterns in the first direction.

3. The 3D FeRAM device of claim 2, wherein a thickness of each of the word lines in the third direction is less than a thickness of the corresponding one of the ferroelectric patterns in the third direction.

4. The 3D FeRAM device of claim 2, wherein an upper surface of each of the word lines is lower than an upper surface of the corresponding one of the ferroelectric patterns, and a lower surface of each of the word lines is higher than a lower surface of the corresponding one of the ferroelectric patterns.

5. The 3D FeRAM device of claim 1, further comprising a gate insulation pattern between each of the channels and a corresponding one of the word lines.

6. The 3D FeRAM device of claim 1, further comprising a gate insulation pattern between each of the channels and a corresponding one of the block selection lines.

7. The 3D FeRAM device of claim 1, wherein a length of each of the capacitor electrodes in the first direction is greater than a length of each of the ferroelectric patterns in the first direction.

8. The 3D FeRAM device of claim 1, wherein a portion of each of the word lines overlaps a portion of a corresponding one of the capacitor electrodes in the third direction.

9. The 3D FeRAM device of claim 1, wherein a first sidewall of each of the capacitor electrodes disposed at a first end in the first direction contacts a corresponding one of the channels, and a second sidewall of each of the capacitor electrodes disposed at a second end opposite the first end in the first direction is covered by an insulation pattern.

10. A 3D FeRAM device, comprising:
a bit line on a substrate, the bit line extending lengthwise in a first direction parallel to an upper surface of the substrate;
a block selection line on the bit line, the block selection line extending lengthwise in a second direction parallel to the upper surface of the substrate and crossing the first direction;
word lines on the block selection line, each of the word lines extending lengthwise in the second direction, and the word lines being spaced apart from each other in a third direction perpendicular to the upper surface of the substrate;
a channel contacting an upper surface of the bit line, the channel being adjacent to the block selection line and the word lines and extending lengthwise in the third direction;
a plate line contacting an upper surface of the channel; and
a capacitor structure including capacitor electrodes and ferroelectric patterns alternately stacked in the third direction on the bit line,
wherein:
the capacitor electrodes of the capacitor structure contact and are electrically connected to the channel,
each of the word lines overlaps a corresponding one of the ferroelectric patterns in the first direction, and
a thickness of each of the word lines in the third direction is less than a thickness of the corresponding one of the ferroelectric patterns in the third direction.

11. The 3D FeRAM device of claim 10, wherein an upper surface of the each of the word lines is lower than an upper surface of the corresponding one of the ferroelectric patterns, and a lower surface of the each of the word lines is higher than a lower surface of the corresponding one of the ferroelectric patterns.

12. The 3D FeRAM device of claim 10, wherein the plate line extends lengthwise in the second direction.

13. The 3D FeRAM device of claim 10, wherein the plate line extends lengthwise in the first direction.

14. The 3D FeRAM device of claim 10, wherein the channel extends through the block selection line and the word lines, and the block selection line and each of the word lines surround a portion of the channel.

15. The 3D FeRAM device of claim 10, wherein the channel is disposed at a side of each of the block selection line and the word lines.

16. The 3D FeRAM device of claim 10, further comprising a gate insulation pattern between the channel and each of the word lines.

17. The 3D FeRAM device of claim 10, wherein a length of each of the capacitor electrodes in the first direction is greater than a length of each of the ferroelectric patterns in the first direction.

18. The 3D FeRAM device of claim 10, wherein a portion of each of the word lines overlaps a portion of a corresponding one of the capacitor electrodes in the third direction.

19. A 3D FeRAM device, comprising:
bit lines on a substrate, each of the bit lines extending lengthwise in a first direction parallel to an upper surface of the substrate, and the bit lines being spaced apart from each other in a second direction parallel to the upper surface of the substrate and crossing the first direction;
block selection lines on the bit lines, each of the block selection lines extending lengthwise in the second direction, and the block selection lines being spaced apart from each other in the first direction;
a set of word lines on each of the block selection lines, each of the word lines for each set extending lengthwise in the second direction, and each set of the word lines including a plurality of word lines spaced apart from each other in a third direction perpendicular to the upper surface of the substrate;
channels spaced apart from each other in the first direction and in the second direction, each of the channels extending lengthwise in the third direction through one of the block selection lines and a corresponding set of the word lines arranged in the third direction on an upper surface of a corresponding one of the bit lines;
a gate insulation pattern between each of the channels and a corresponding one of the block selection lines and between each of the channels and a corresponding one of the word lines;
plate lines each contacting upper surfaces of the channels arranged in the second direction, and the plate lines being spaced apart from each other in the first direction;
insulation patterns on each of the bit lines; and
capacitor structures spaced apart from each other in the first direction, each of the capacitor structures including capacitor electrodes and ferroelectric patterns alternately stacked in the third direction on each of the insulation patterns,
wherein:
the capacitor electrodes of each of the capacitor structures contact and are electrically connected to a corresponding one of the channels,
each of the channels, a corresponding one of the block selection lines and a corresponding set of the word lines surrounding the corresponding channel, capacitor electrodes of a corresponding one of the capacitor structures contacting the corresponding channel, and the ferroelectric patterns between the capacitor electrodes collectively form a memory cell chain, and
a plurality of memory cell chains arranged in the second direction collectively form a memory cell block.

20. The 3D FeRAM device of claim 19, wherein each of the word lines overlaps a corresponding one of the ferroelectric patterns in the first direction.
